(19) United States
(12) Patent Application Publication
(10) Pub. No.: US 2026/0354075 A1
(43) Pub. Date: Nov. 5, 2026

(54) DRAIN APPARATUS AND SUBSTRATE PROCESSING APPARATUS INCLUDING THE SAME

(71) Applicant: SEMES CO., LTD., Cheonan-si (KR)

(72) Inventors: Gu Won SEON, Seoul (KR); Jae Seung YU, Seoul (KR)

(73) Assignee: SEMES CO., LTD., Cheonan-si (KR)

(21) Appl. No.: 19/372,478

(22) Filed: Oct. 29, 2025

(30) Foreign Application Priority Data
Oct. 30, 2024 (KR) 10-2024-0151150

(51) Int. Cl. H10P 72/00

(52) U.S. Cl. CPC H10P 72/0404

(57) ABSTRACT

Provided is an apparatus for processing a substrate, the apparatus including: a processing unit for processing a substrate; a liquid supply unit for supplying a liquid to the substrate disposed in the processing unit; and a drain apparatus for discharging a liquid drained from the processing unit or the liquid supply unit to the outside, in which the drain apparatus includes: a drain box having an inner space; an inlet pipe for flowing the liquid drained from the processing unit or liquid supply unit into the inner space; a gas supply unit for supplying gas to the inner space through a gas supply pipe; a discharge pipe for discharging the liquid in the inner space to the outside of the drain box; and a recovery pipe that is branched from the inlet pipe and recovers a fluid flowing back to the inlet pipe from the inner space to the drain box. The present invention may prevent a liquid or fume from flowing back from the drain apparatus to the liquid supply unit or the processing unit.

### CROSS-REFERENCE TO RELATED APPLICATION

This application claims priority to and the benefit of Korean Patent Application No. 10-2024-0151150 filed in the Korean Intellectual Property Office on Oct. 30, 2024, the entire contents of which are incorporated herein by reference.

### TECHNICAL FIELD

The present invention relates to a drain apparatus, and a substrate processing apparatus including the same.

### BACKGROUND ART

In order to manufacture a semiconductor device, various processes, such as cleaning, deposition, photography, etching, and ion implantation, are performed. Among the processes, the photography process includes a coating process of forming a film by coating a surface of the substrate with a photosensitive liquid, such as photoresist, an exposure process that transfers a circuit pattern to a film formed on the substrate, and a developing process that selectively removes a film formed on the substrate in a region on which the exposure process has been performed or a region opposite to the region.

Typically, a device that performs a coating process supplies a liquid, such as photoresist, from a nozzle onto a rotating substrate to form a liquid film on the substrate. As illustrated in FIG. 1, in a liquid supply unit 5100 for supplying a liquid to a nozzle 5190, a gas supply unit 5120 supplies gas to a bottle 5110 and supplies the liquid in the bottle 5110 to a trap tank 5140 through a liquid supply pipe 5130. A pump 5150 and a filter 5170 for providing flow pressure are provided in the liquid supply pipe 5130 at the downstream side of the trap tank 5140 so that the liquid in the trap tank 5140 flows to the nozzle 5190, and impurities in the liquid are filtered. The liquid filtered by the filter 570 is drained to a drain apparatus 5300 and discharged to the outside.

Referring to FIG. 2, the drain apparatus 5300 includes a drain box 5310, an inlet pipe 5330 for flowing the liquid drained from the filter 5170 to the drain box 5310, a thinner supply unit 5350, a discharge pipe 5370 for discharging the liquid to the outside, and a gas supply unit 5390. The gas supply pipe 5390 supplies high-pressure gas into the drain box 5310, mixes the liquid with the thinner, and discharges the liquid to the discharge pipe 5370.

Due to the supply of gas, as the pressure inside the drain box 5310 increases, the liquid or fume in the drain box 5310 flows back into the inlet pipe 5330, and the contaminated liquid or fume flows into the filter 5170 due to the failure or damage of the check valve 5331 installed in the inlet pipe 5330. There is a problem in that the liquid or fume flowing back into the filter 5170 contaminates the configurations of the liquid supply unit 5100 and the substrate W while flowing through the liquid supply pipe 5130.

### SUMMARY OF THE INVENTION

The present invention has been made in an effort to provide a drain apparatus capable of efficiently discharging a liquid for processing a substrate and a substrate processing apparatus including the same.

The present invention has also been made in an effort to provide a drain apparatus for preventing a liquid in a drain apparatus from flowing back to an external configuration and a substrate processing apparatus including the same.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a processing unit for processing a substrate; a liquid supply unit for supplying a liquid to the substrate disposed in the processing unit; and a drain apparatus for discharging a liquid drained from the processing unit or the liquid supply unit to the outside, wherein the drain apparatus may includes, a drain box having an inner space; an inlet pipe for flowing the liquid drained from the processing unit or liquid supply unit into the inner space; a gas supply unit for supplying gas to the inner space through a gas supply pipe; a discharge pipe for discharging the liquid in the inner space to the outside of the drain box; and a recovery pipe that is branched from the inlet pipe and recovers a fluid flowing back to the inlet pipe from the inner space to the drain box.

According to the exemplary embodiment of the present invention, wherein a negative pressure forming unit may be coupled to the recovery pipe.

According to the exemplary embodiment of the present invention, wherein the recovery pipe is connected to the gas supply pipe, and an opening/closing valve may be installed in the recovery pipe.

According to the exemplary embodiment of the present invention, wherein an ejector having an inlet, an outlet, and a suction port is installed in the gas supply pipe, a pipe located on a gas supply source side in the gas supply pipe is connected to the inlet, a pipe located on the drain box side in the gas supply pipe is connected to the outlet, and the recovery pipe may be connected to the suction port.

According to the exemplary embodiment of the present invention, wherein an opening/closing valve is installed in the recovery pipe, and the drain apparatus further may includes: a differential pressure sensor for measuring a difference between a pressure of the gas supply pipe and a pressure of the recovery pipe; and a controller for controlling the opening/closing valve installed in the recovery pipe based on a value measured by the differential pressure sensor.

According to the exemplary embodiment of the present invention, wherein the controller closes the opening/closing valve when a differential pressure measured by the differential pressure sensor exceeds a set value, and opens the opening/closing valve when the differential pressure measured by the differential pressure sensor may be equal to or less than the set value.

According to the exemplary embodiment of the present invention, wherein a check valv for preventing backflow is installed in the inlet pipe upstream of a point where the recovery pipe may be branched.

According to the exemplary embodiment of the present invention, wherein the drain apparatus further may includes a dissolution liquid supply pipe for supplying a dissolution liquid for dissolving the liquid in the inner space to the inner space.

According to the exemplary embodiment of the present invention, wherein the liquid supply unit includes: a bottle in which the liquid is stored; a liquid supply pipe for supplying the liquid in the bottle to the processing unit; and a filter installed in the liquid supply pipe, and the filter may have a drainage pipe coupled to the inlet pipe.

An exemplary embodiment of the present disclosure, a drain apparatus for discharging a liquid, the drain apparatus may comprising, a drain box having an inner space; an inlet pipe for flowing a liquid drained from an external configuration into the inner space; a gas supply unit for supplying gas to the inner space through a gas supply pipe; a dissolution liquid supply pipe for supplying a dissolution liquid into the inner space to dissolve the liquid in the inner space; a discharge pipe for discharging the liquid in the inner space to the outside of the drain box; and a recovery pipe that is branched from the inlet pipe and recovers a fluid flowing back to the inlet pipe from the inner space to the drain box.

According to the exemplary embodiment of the present invention, wherein the recovery pipe is connected to the gas supply pipe, and an opening/closing valve may be installed in the recovery pipe.

According to the exemplary embodiment of the present invention, wherein an ejector having an inlet, an outlet, and a suction port is installed in the gas supply pipe, a pipe located on a gas supply source side in the gas supply pipe is connected to the inlet, a pipe located on the drain box side in the gas supply pipe is connected to the outlet, and the recovery pipe may be connected to the suction port.

According to the exemplary embodiment of the present invention, wherein an opening/closing valve is installed in the recovery pipe, and the drain apparatus further may comprises: a differential pressure sensor for measuring a difference between a pressure of the gas supply pipe and a pressure of the recovery pipe; and a controller for controlling the opening/closing valve installed in the recovery pipe based on a value measured by the differential pressure sensor.

According to the exemplary embodiment of the present invention, wherein the controller closes the opening/closing valve when a differential pressure measured by the differential pressure sensor exceeds a set value, and opens the opening/closing valve when the differential pressure measured by the differential pressure sensor may be equal to or less than the set value.

According to the exemplary embodiment of the present invention, wherein the inlet pipe includes: a first inlet pipe for flowing a liquid drained from a first configuration into the inner space; and a second inlet pipe for flowing a liquid drained from a second configuration into the inner space, and the recovery pipe may includes: a first recovery pipe for recovering a fluid flowing back from the inner space to the first inlet pipe to the drain box; and a second recovery pipe for recovering a fluid flowing back from the inner space to the second inlet pipe to the drain box.

According to the exemplary embodiment of the present invention, wherein the gas supply pipe is provided with a first ejector having a first inlet, a first outlet, and a first suction port, and a second ejector having a second inlet, a second outlet, and a second suction port, a pipe located on a gas supply source side in the gas supply pipe is connected to the first inlet, a pipe located on the drain box side in the gas supply pipe is connected to the first outlet, the first recovery pipe is connected to the first suction port, a pipe located on a gas supply source side in the gas supply pipe is connected to the second inlet, a pipe located on the drain box side in the gas supply pipe is connected to the second outlet, and the second recovery pipe may be connected to the second suction port.

According to the exemplary embodiment of the present invention, the apparatus further includes a first differential pressure sensor for measuring a difference between a pressure of the gas supply pipe and a pressure of the first recovery pipe; a second differential pressure sensor for measuring a difference between a pressure of the gas supply pipe and a pressure of the second recovery pipe; a first opening/closing valve for opening/closing the first recovery pipe; and a second opening/closing valve for opening/closing the second recovery pipe.

According to the exemplary embodiment of the present invention, the apparatus further includes a controller for controlling the first opening/closing valve and the second opening/closing valve, the controller closes the first opening/closing valve when a differential pressure measured by the first differential pressure sensor exceeds a set value, and opens the first opening/closing valve when the differential pressure measured by the first differential pressure sensor is equal to or less than the set value, and closes the second opening/closing valve when a differential pressure measured by the second differential pressure sensor exceeds a set value, and opens the second opening/closing valve when the differential pressure measured by the second differential pressure sensor is equal to or less than the set value.

An exemplary embodiment of the present disclosure, an apparatus for processing a substrate, the apparatus comprising: a processing unit for processing a substrate; a liquid supply unit for supplying a photoresist to the substrate disposed in the processing unit; and a drain apparatus for discharging the photoresist drained from the liquid supply unit to the outside, the drain apparatus includes: a drain box having an inner space; an inlet pipe for flowing the photoresist drained from the liquid supply unit into the inner space; a gas supply unit for supplying gas to the inner space through a gas supply pipe; a thinner supply pipe for supplying a thinner to dissolve the photoresist in the inner space; a discharge pipe for discharging the liquid in the inner space to the outside of the drain box; a recovery pipe that is branched from the inlet pipe and recovers a fluid flowing back to the inlet pipe from the inner space to the drain box; an opening/closing valve for opening and closing the recovery pipe; and an ejector installed in the gas supply pipe and having an inlet, an outlet, and a suction port, and a pipe located on a gas supply source side of the gas supply pipe is connected to the inlet, a pipe located on the drain box side in the gas supply pipe may be connected to the outlet, and the recovery pipe is connected to the suction port.

According to the exemplary embodiment of the present invention, the apparatus further includes a controller for controlling the drain apparatus, wherein the drain apparatus further includes a differential pressure sensor that measures a difference between a pressure of the gas supply pipe and a pressure of the recovery pipe, and the controller closes the opening/closing valve when a differential pressure measured by the differential pressure sensor exceeds a set value, and opens the opening/closing valve when the differential pressure measured by the differential pressure sensor may be equal to or less than the set value.

According to the exemplary embodiment of the present invention, it is possible to improve substrate processing efficiency.

According to the exemplary embodiment of the present invention, it is possible to prevent the liquid in the drain apparatus from flowing back to an external configuration.

According to the exemplary embodiment of the present invention, it is possible to reduce the internal pressure of the drain apparatus.

According to the exemplary embodiment of the present invention, it is possible to recover the liquid flowing back inside the drain apparatus to the drain apparatus again.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram illustrating an example of a general liquid supply unit for supplying a liquid to a nozzle.

FIG. 2 is a diagram illustrating an example of a general drain apparatus.

FIG. 3 is a diagram schematically illustrating a substrate processing apparatus according to an exemplary embodiment of the present invention.

FIG. 4 is a diagram schematically illustrating an example of a processing unit of FIG. 3.

FIG. 5 is a schematic perspective view illustrating an example of a drain apparatus of FIG. 3.

FIG. 6 is a front view of the drain apparatus of FIG. 5.

FIGS. 7 to 8 are diagrams schematically illustrating a liquid recovering method of the drain apparatus according to an exemplary embodiment.

FIG. 9 is a diagram schematically illustrating a structure of the liquid supply unit according to another exemplary embodiment.

FIG. 10 is a diagram schematically illustrating an example of the drain apparatus of FIG. 9.

FIG. 11 is a diagram schematically illustrating another exemplary embodiment of the drain apparatus of FIG. 9.

FIG. 12 is a diagram schematically illustrating another exemplary embodiment of the substrate processing apparatus of FIG. 2.

FIG. 13 is a diagram schematically illustrating another exemplary embodiment of the drain apparatus of FIG. 6.

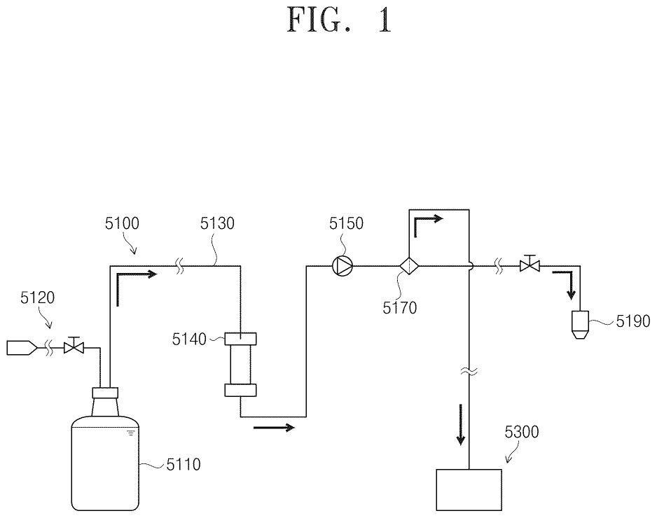

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ~ and ~”, “just between ~ and ~”, or “adjacent to ~” and “directly adjacent to ~” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

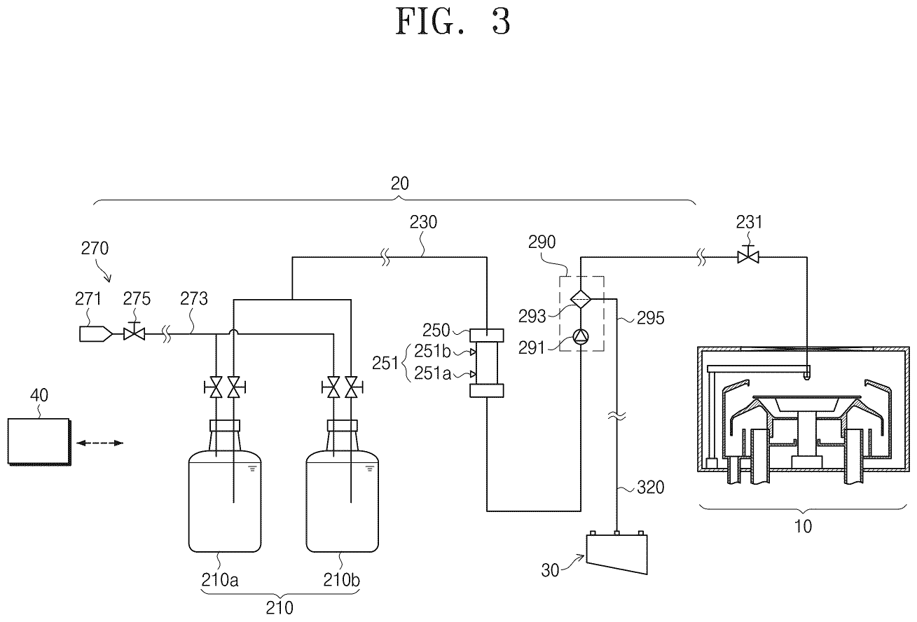

Hereinafter, an exemplary embodiment of the present invention will be described with reference to FIGS. 3 to 13.

In the following exemplary embodiment, the case where a substrate processing apparatus is an apparatus for performing a coating process of coating a photoresist on a substrate will be described as an example. However, unlike this, the substrate processing apparatus may be an apparatus for coating an antireflection film, a protective film, or another kind of liquid onto a substrate.

FIG. 3 is a diagram schematically illustrating a substrate processing apparatus according to an exemplary embodiment of the present invention. Referring to FIG. 3, a substrate processing apparatus 1 includes a processing unit 10, a liquid supply unit 20, a drain apparatus 30, and a controller 40.

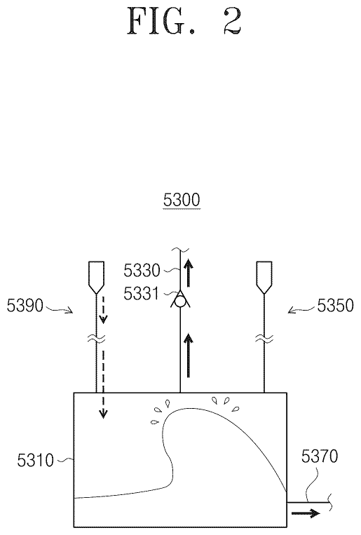

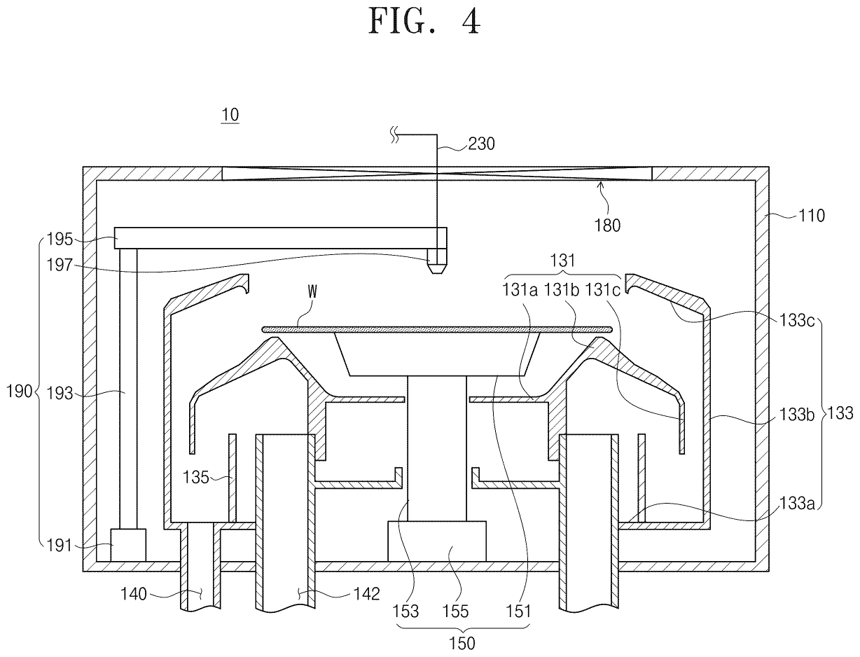

FIG. 4 is a diagram schematically illustrating an example of a processing unit of FIG. 3. Referring to FIG. 2, the processing unit 10 may include a housing 110, a cup 133, a support unit 150, a guide ring 131, an airflow supply unit 180, and a nozzle unit 190.

The housing 110 provides space therein. The housing 110 is provided in a generally rectangular parallelepiped shape. An opening (not illustrated) is formed at one side of the housing 110. The opening (not illustrated) functions as an entrance through which the substrate W is loaded into the inner space or the substrate W is unloaded from the inner space. Also, a door (not illustrated) is installed in an area adjacent to the entrance to selectively open and close the entrance. A door (not illustrated) blocks the entrance and seals the inner space from the outside while the processing process is performed on the substrate W loaded into the inner space. The cup 133, the support unit 150, the guide ring 131, and the nozzle unit 190 may be disposed in the inner space of the housing 110.

The cup 133 may be provided to surround the support unit 150 and the guide ring 131. The cup 133 may include a bottom wall 133a, a sidewall 133b, and an upper wall 133c.

The bottom wall 133a may have a circular plate shape having a hollow. A discharge pipe 140 is connected to the bottom wall 133a. After processing the substrate W, the liquid scattered from the substrate W is discharged to the outside of the cup 133 through the discharge pipe 140.

An exhaust pipe 142 is connected to the bottom wall 133a. The exhaust pipe 142 is connected to the bottom wall 133a from the inner side than the exhaust pipe 140. Fume and airflow flowing in the cup 133 are exhausted to the outside of the cup 133 through the exhaust pipe.

A gas-liquid separation plate 135 may be installed on the bottom wall 133a. The gas-liquid separation plate 135 may be provided in an annular shape. The gas-liquid separation plate 135 is installed between the discharge pipe 140 and the exhaust pipe 142. The gas-liquid separation plate 135 prevents liquids used for processing the substrate W from flowing into the exhaust pipe 142.

The sidewall 133b may be provided in an annular ring shape surrounding the guide ring 131. The sidewall 133b may extend in a vertical direction from a side end of the bottom wall 133a.

The upper wall 133c may extend in a direction from an upper end of the sidewall 133b toward a central axis of the outer cup 133. An inner surface of the upper wall 133c may extend to be inclined upward with respect to the ground as it approaches a central axis of the outer cup 133. The upper wall 133c may be provided to have a ring shape when viewed from above. While the processing of the substrate W is performed, the upper end of the upper wall 133c may be positioned to be higher than the upper surface of the substrate W supported by the support unit 150.

The support unit 150 supports and rotates the substrate W in a processing space. The support unit 150 may be a spin chuck that supports and rotates the substrate W. The support unit 150 may include a body 151, a support shaft 153, and a driving unit 155.

The guide ring 131 may have an inner wall 131a, an upper wall 131b, and an outer wall 131c. The inner wall 131a, the upper wall 131b, and the outer wall 131c may be combined with each other to provide a space in which the lower portion is open. The support shaft 153 of the support unit 150 may be surrounded by the inner wall 131a. The outer wall 131c may be combined with the cup 133 to form a discharge path through which the processing medium is discharged. The upper wall 131b may be provided to be inclined upward toward the outside from the inner wall 131a, and may then have a shape inclined downward toward the outer wall 131c.

The body 151 may have a top surface on which the substrate W is seated. The top surface of the body 151 may be provided in an approximately circular shape when viewed from the top. The top surface of the body 151 may have a diameter smaller than that of the substrate W. An adsorption hole (not illustrated) may be formed in the body 151. The adsorption hole (not illustrated) may vacuum-adsorb the substrate W seated on the top surface of the body 151.

The support shaft 153 is coupled with the body 151. The support shaft 153 may be coupled to a lower surface of the body 151. The longitudinal direction of the support shaft 153 may be provided in a vertical direction. The driving unit 155 may provide power for rotating the support shaft 153 with respect to a central axis thereof and for moving the support shaft 153 in a vertical direction. Accordingly, a relative height between the support unit 150 and the cup 133 may be adjusted.

An airflow supply unit 180 is installed on an upper end of the housing 110. The airflow supply unit 180 may supply airflow having a temperature and/or humidity adjusted to the inner space. The airflow supply unit 180 may be a Fan Filter Unit (FFU).

The nozzle unit 190 is provided in the housing 110. The nozzle unit 190 receives a liquid from the liquid supply unit 20 and supplies the liquid to the substrate W supported by the support unit 150. The nozzle unit 190 may include a driver 191, a support rod 193, an arm 195, and a nozzle 197.

The support rod 193 is located in the inner space of the housing 110. The support rod 193 is located on one side of a processing container 420 in the inner space. The support rod 193 may have a rod shape whose longitudinal direction faces a vertical direction.

The arm 195 is coupled to an upper end of the support rod 193. The arm 195 extends vertically from the longitudinal direction of the support rod 193. The nozzle 197 may be fixedly coupled to the end of the arm 195.

The driver 191 is coupled with the support rod 193. The driver 191 may be disposed on the bottom surface of the housing 110. The driver 191 provides driving force for rotating the support rod 193. The driver 191 may be provided as a motor.

The liquid supply unit 20 supplies photoresist to the nozzle 197 provided in the processing unit 10.

Referring to FIG. 3, the liquid supply unit 20 may include a bottle 210, a liquid supply pipe 230, a trap tank 250, a gas supply member 270, and a pump unit 290.

The bottle 210 stores a photoresist. A plurality of bottles 210a and 210b may be provided. For example, the bottles 210a and 210b may include a first bottle 210a and a second bottle 210b. Accordingly, first, the liquid may be supplied from the first bottle 210a to the trap tank 250 to be described later, and when the internal liquid of the first bottle 210a is exhausted, the liquid may be supplied from the second bottle 210b to the trap tank 250. While the liquid is supplied from the second bottle 210b, the first bottle 210a may be replaced with a new bottle. The first bottle 210a and the second bottle 210b have the same structure.

The liquid supply pipe 230 may supply the liquid in the bottle 210 to the processing unit 10. The trap tank 250 and the pump unit 290 may be installed in the liquid supply pipe 230. The liquid supply pipe 230 may be provided with a valve 231 for opening and closing the internal flow path thereof.. The valve 231 may be an on/off valve. A flow rate control valve may be optionally further provided. Whether or not to supply a photoresist supplied to the processing space of the processing unit 10 and an amount of photoresist supplied are determined by opening and closing of the valve 231. The valve 231 may be installed on the downstream side of the liquid supply pipe 230 relative to the pump unit 290.

The trap tank 250 may temporarily store the photoresist supplied from the bottle 210. A water level detection sensor 251 is installed at one side of the trap tank 250 to detect the water level of the photoresist remaining in the trap tank 250. A plurality of water level detection sensors 251 may be provided. For example, a first water level detection sensor 251a installed at the lower end side of the trap tank 250 and a second water level detection sensor 251b installed at the upper end side of the trap tank 250 may be installed.

The gas supply member 270 provides gas pressure and causes the liquid in the bottle 210 to flow into the trap tank 250. The gas supply member 270 includes a gas supply source 271 and a gas supply pipe 273. The gas supply source 271 stores gas. According to an exemplary embodiment, the gas may be inert gas. For example, the gas may be nitrogen gas (N₂). The gas supply pipe 273 is connected to the bottle 210, and supplies the gas stored in the gas supply source 271 to the bottle 210. The gas supply pipe 273 is provided with an opening/closing valve 275 capable of opening and closing an internal flow path thereof.

The pump unit 290 may be installed on the downstream side of the liquid supply pipe 230 relative to the trap tank 250. The pump unit 290 includes a pump 291 and a filter 293. The pump 291 provides a flow pressure at which the photoresist in the trap tank 250 may flow to the processing unit 10. The filter 293 filters contaminants inside the photoresist supplied to the processing unit 10.

After the photoresist in the trap tank 250 is dispensed into the processing unit 10 by the pump 291, a part of the photoresist remains in the filter 293, and the remaining photoresist is drained from the filter 293 through a drainage pipe 295. The drainage pipe 295 is connected to an inlet pipe 320 to be described later, and drains the drained photoresist into the drain box 310. The filter 293 may be installed on the downstream side of the liquid supply pipe 230 relative to the pump 291.

The drain apparatus 30 discharges the photoresist or fume drained from the external configuration to the outside. According to an example, the drain apparatus 30 may discharge the photoresist or fume drained from the filter 293 of the liquid supply unit 20 to the outside.

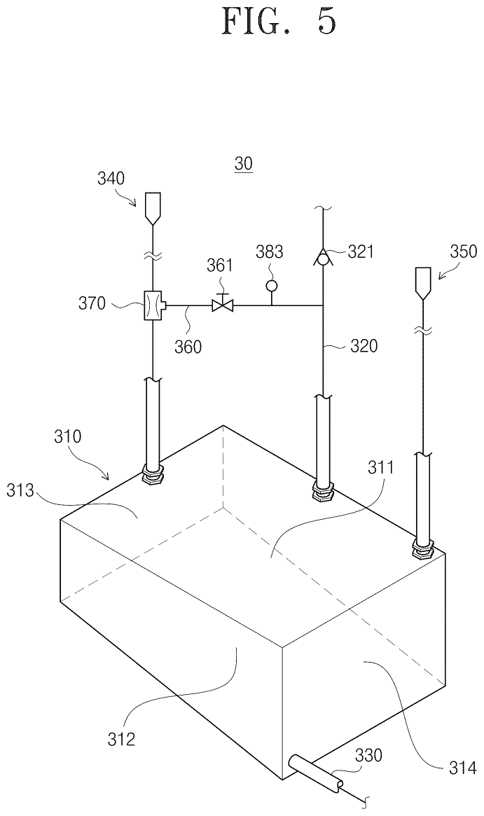

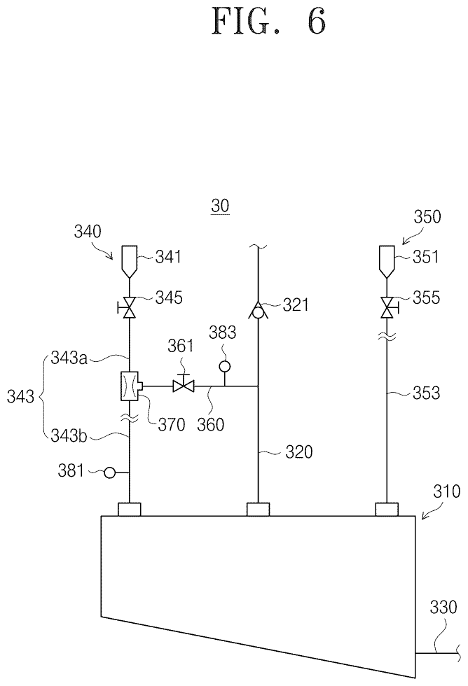

FIGS. 5 to 6 are diagrams schematically illustrating an example of the drain apparatus of FIG. 3.

The drain apparatus 30 may include a drain box 310, an inlet pipe 320, a discharge pipe 330, a gas supply unit 340, a dissolution liquid supply unit 350, and a recovery pipe 360.

The drain box 310 has an inner space. A photoresist drained through the inlet pipe 320 may temporarily remain in the inner space of the drain box 310. The inlet pipe 320, the discharge pipe 330, the gas supply pipe 343, and the dissolution liquid supply pipe 353 to be described later may be connected to the drain box 310.

The bottom surface 312 of the drain box 310 may be provided to be inclined downward from one side toward the other side. According to an example, the bottom surface 312 may be provided to be inclined downward from a first side surface 313 of the hole side to which the gas supply pipe 343 is connected to a second side surface 314 of the hole side to which the discharge pipe 330 is connected. Accordingly, the photoresist inside the drain box 310 may be efficiently discharged to the outside through the discharge pipe 330.

The inlet pipe 320 is connected to the drainage pipe 295 and flows the photoresist drained from the filter 293 to the drain box 310. A check valve 321 may be installed in the inlet pipe 320 to prevent backflow of the photoresist.

The gas supply unit 340 supplies high-pressure gas to the inner space of the drain box 310 to discharge the photoresist remaining in the inner space to the discharge pipe 330.

The gas supply unit 340 includes a gas supply source 341 and a gas supply pipe 343. The gas supply source 341 stores high-pressure gas. According to an example, the gas may be inert gas. For example, the gas may be nitrogen gas (N₂).

The gas supply pipe 343 is connected to the drain box 310 and supplies the gas stored in the gas supply source 341 to the inner space. According to an example, the gas supply pipe 343 may be connected to the edge side of an upper surface 311 of the drain box 310. For example, the gas supply pipe 343 may be connected to the first side surface 313 from the upper surface 311 of the drain box 310. The gas supply pipe 343 may be provided with an opening/closing valve 345 for opening and closing the internal flow path thereof.

The dissolution liquid supply unit 350 supplies the dissolution liquid to the inner space of the drain box 310. The dissolution liquid supply unit 350 includes a dissolution liquid supply source 351 and a dissolution liquid supply pipe 353. The dissolution liquid supply source 351 stores the dissolution liquid. The dissolution liquid may be a solution that dissolves a photoresist to prevent solidification. According to an example, the dissolution liquid may be a thinner. The dissolution liquid supply pipe 353 is connected to the drain box 310 to supply the dissolution liquid stored in the dissolution liquid supply source 351 to the inner space. The dissolution liquid supplied to the inner space is uniformly mixed with the photoresist by the gas supplied by the gas supply unit 340 and dissolves the photoresist. The dissolution liquid supply pipe 353 may be provided with an opening/closing valve 355 for opening and closing the internal flow path thereof.

The recovery pipe 360 is branched from the inlet pipe 320 to recover a photoresist or fume flowing back to the inlet pipe 320 to the drain box 310. According to an example, the recovery pipe 360 may be branched from the inlet pipe 320 at the downstream side relative to the check valve 321. The recovery pipe 360 is provided with an opening/closing valve 361 for opening and closing the internal flow path thereof.

An ejector 370 having an inlet, an outlet, and a suction port may be installed in the gas supply pipe 343, and the recovery pipe 360 may be connected to the suction port of the ejector 370. A gas supply pipe 343a connected to the gas supply source 341 of the gas supply pipe 343 may be connected to the inlet of the ejector 370, and a gas supply pipe 343b connected to the drain box 310 of the gas supply pipe 343 may be connected to the outlet.

The high-pressure gas supplied by the gas supply source 341 flows inside the ejector 370 through the gas supply pipe 343 to form a negative pressure in the ejector 370. The photoresist or fume flowing back to the inlet pipe 320 sequentially flows through the recovery pipe 360 and the gas supply pipe 343 by the negative pressure formed inside the ejector 370 and is recovered to the drain box 310.

Differential pressure sensors 381 and 383 are installed in the gas supply pipe 343 and the recovery pipe 360 to measure the difference between the internal pressure of the gas supply pipe 343 and the internal pressure of the recovery pipe 360.

The controller 30 may control the drain apparatus 30 and the substrate processing apparatus 1 including the same to perform the substrate processing method described below. The controller 40 may control the opening/closing valve 361 in the recovery pipe 360 to close the opening/closing valve 361 when the differential pressure measured by the differential pressure sensor exceeds a set value, and to open the opening/closing valve 361 when the differential pressure is equal to or less than the set value.

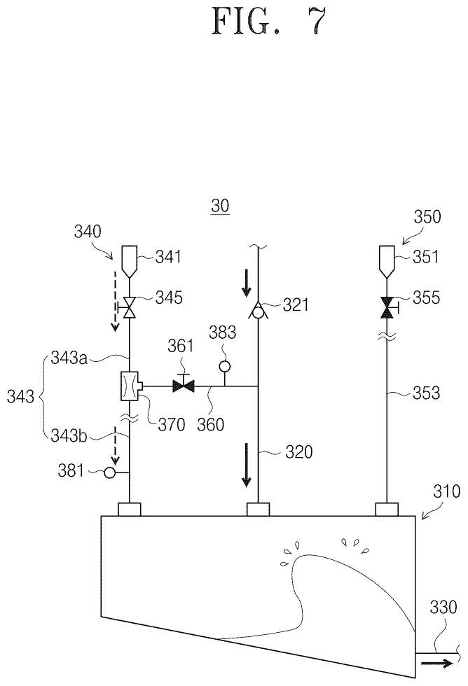

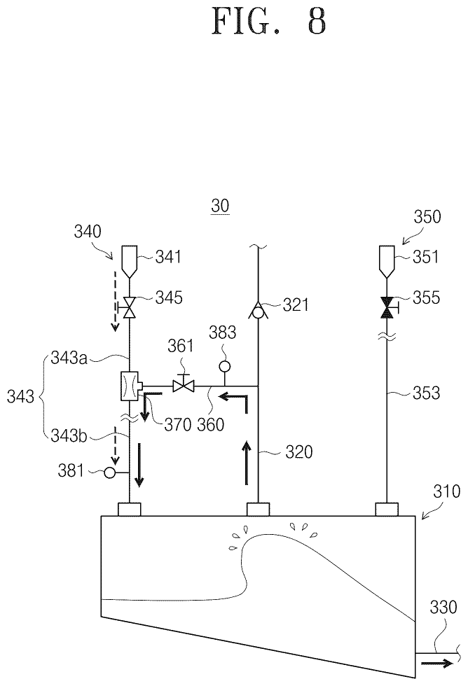

FIGS. 7 to 8 are diagrams schematically illustrating a liquid recovering method of the drain apparatus according to an exemplary embodiment. In FIGS. 7 to 8, the valve with the filled inside is in a closed state for preventing the fluid from flowing, and the valve with an empty inside is in an open state for allowing the fluid to flow. In addition, the dotted arrow indicates the flow direction of the inert gas, and the solid arrow indicates the flow direction of the photoresist.

Referring to FIG. 7, a photoresist is introduced into the drain box 310 through the inlet pipe 320, and the introduced photoresist or fume is discharged to the discharge pipe 330 by the gas supplied by the gas supply unit 340. When the differential pressure measured by the differential pressure sensors 381 and 383 is greater than a set value, and the opening/closing valve 361 in the recovery pipe 360 is closed.

Thereafter, when the pressure in the inner space of the drain box 310 is increased by the supply of gas and the differential pressure measured by the differential pressure sensors 381 and 383 becomes less than or equal to the set value, as illustrated in FIG. 8, the opening/closing valve 361 in the recovery pipe 360 is opened, and the photoresist or fume flowing back to the inlet pipe 320 flows through the recovery pipe 360 and the gas supply pipe 343 by the negative pressure formed inside the ejector 370 and is recovered to the drain box 310 again. Accordingly, when the pressure in the inner space of the drain box 310 is lowered and the differential pressure measured by the differential pressure sensors 381 and 383 becomes less than or equal to the set value, the opening/closing valve 361 in the recovery pipe 360 is closed and the process of FIG. 7 is repeated.

According to the present invention, by recovering the photoresist or fume flowing back to the drain box 310 due to an increase in pressure in the inner space of the drain box 310, contaminated photoresist or fume may be prevented from flowing back to the filter 293 to contaminate the configuration of the liquid supply unit 20 and the substrate W, and the pressure of the inner space of the drain box 310 may be lowered.

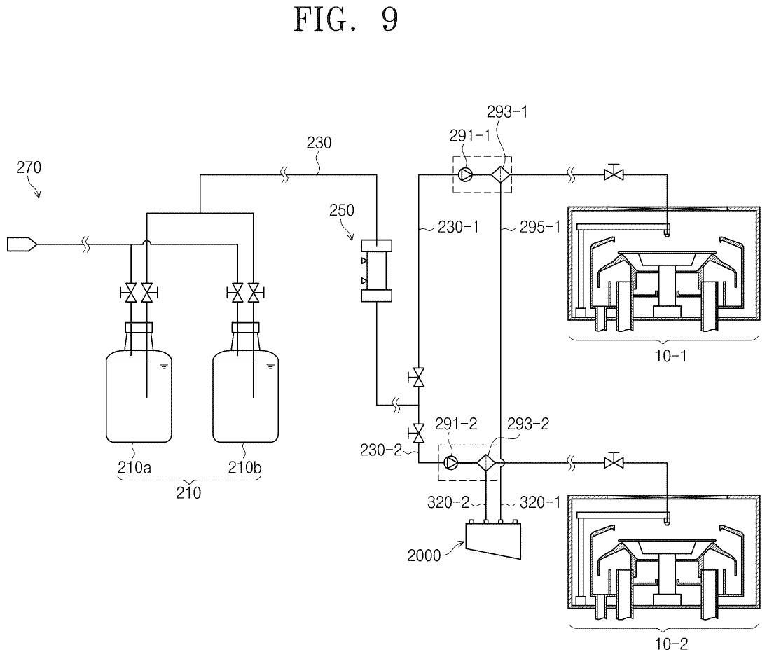

In the exemplary embodiment of FIG. 2 described above, the present invention has been described based on the case where the liquid supply unit 20 supplies the liquid to one processing unit 10 through one liquid supply pipe 230 as an example. However, the present invention is not limited thereto, and as illustrated in FIG. 9, the liquid supply pipe 230 is branched at the downstream side of the trap tank 250 to a first liquid supply pipe 230-1 and a second liquid supply pipe 230-2, and the first liquid supply pipe 230-1 and the second liquid supply pipe 230-2 may supply the liquid to a first processing unit 10-1 and a second processing unit 10-2, respectively. A first pump 291-1 and a first filter 293-1, and a second pump 291-2 and a second filter 293-2 may be installed in the first liquid supply pipe 230-1 and the second liquid supply pipe 230-2, respectively. The liquid remaining in the first filter 293-1 and the second filter 293-2 is drained into a drain apparatus 2000 through a first drainage pipe 295-1 connected to a first inlet pipe 320-1 and a second drainage pipe 295-2 connected to a second inlet pipe 320-2, respectively.

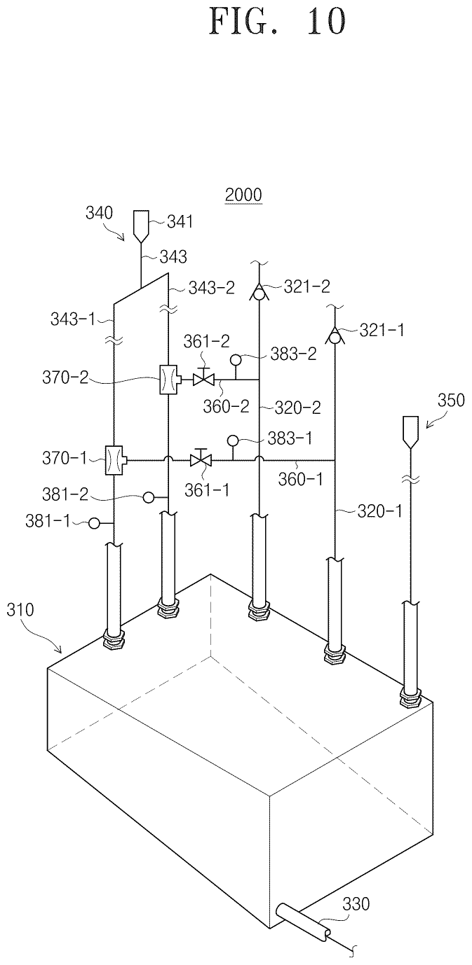

FIG. 10 is a diagram schematically illustrating an example of the drain apparatus of FIG. 9. Since the structure of the drain apparatus 2000 according to the exemplary embodiment described below is mostly the same as or similar to the configuration of the drain apparatus 30 of FIG. 5 described above except for additional descriptions, descriptions of overlapping contents will be omitted.

Referring to FIG. 10, a first inlet pipe 320-1 and a second inlet pipe 320-2 are connected to the drain box 310. A first recovery pipe 360-1 is branched from the first inlet pipe 320-1 to recover the liquid or fume flowing back to the first inlet pipe 320-1 to the drain box 310, and a second recovery pipe 360-2 is branched from the second inlet pipe 320-2 to recover the liquid or fume flowing back to the second inlet pipe 320-2 to the drain box 310.

The gas supply pipe 343 is branched into a first gas supply pipe 343-1 and a second gas supply pipe 343-2, a first ejector 370-1 is installed in the first gas supply pipe 343-1, and a second ejector 370-2 is installed in the second gas supply pipe 343-2, and a negative pressure is formed inside the first ejector 370-1 and the second ejector 370-2 by the flow of the gas. The first recovery pipe 360-1 is connected to the suction port of the first ejector 370-1, and the second recovery pipe 360-2 is connected to the suction port of the second ejector 370-2. The liquid or fume flowing back to the first inlet pipe 320-1 by the negative pressure formed inside the first ejector 370-1 is recovered to the drain box 310 through the first recovery pipe 360-1 and the first gas supply pipe 343-1, and the liquid or fume flowing back to the second inlet pipe 320-2 by the negative pressure formed inside the second ejector 370-2 is recovered to the drain box 310 through the second recovery pipe 360-2 and the second gas supply pipe 343-2.

The first gas supply pipe 343-1 and the first recovery pipe 360-1 may be provided with differential pressure sensors 381-1 and 383-1 that measure a difference between the internal pressure of the first gas supply pipe 343-1 and the internal pressure of the first recovery pipe 360-1, and the second gas supply pipe 343-2 and the second recovery pipe 360-2 may be provided with differential pressure sensors 381-2 and 383-2 that measure a difference between the internal pressure of the second gas supply pipe 343-2 and the internal pressure of the second recovery pipe 360-2. Each of the first gas supply pipe 343-1 and the second gas supply pipe 343-2 may be connected to the drain box 310. However, the present invention is not limited thereto, and the first gas supply pipe 343-1 and the second gas supply pipe 343-2 may be joined in one pipe on the downstream side of the first and second ejectors 370-1 and 370-2 and may be connected to the drain box 310.

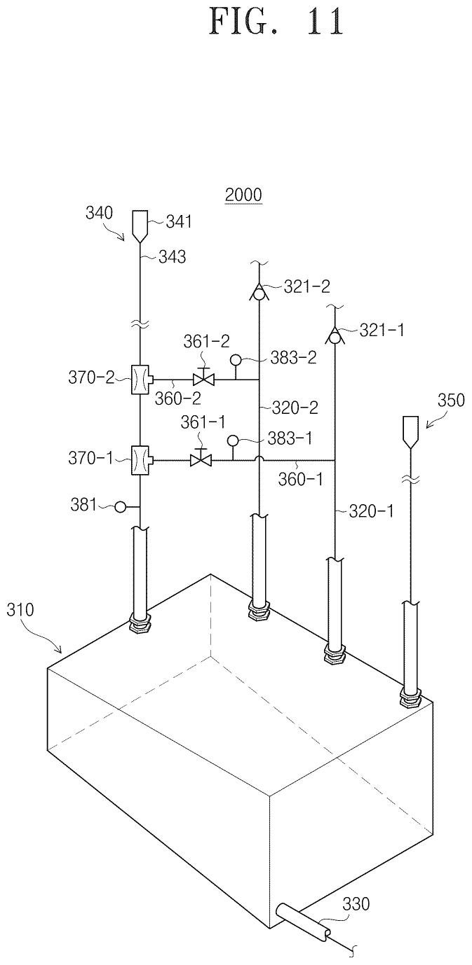

In the above-described exemplary embodiment of FIG. 10, the present invention has been described based on the case where the gas supply pipe 343 is branched into the first gas supply pipe 343-1 and the second gas supply pipe 343-2, and the ejector is installed in each of the first gas supply pipe 343-1 and the second gas supply pipe 343-2 as an example. However, the present invention is not limited to this, and as illustrated in FIG. 11, the gas supply pipe 343 does not branch to the first gas supply pipe 343-1 and the second gas supply pipe 343-2, and the first ejector 370-1 and the second ejector 370-2 may be connected to the gas supply pipe 343 at different locations. In the differential pressure sensor 381 installed in the gas supply pipe 343, the differential pressure sensor 383-1 installed in the first recovery pipe 360-1 may measure a difference between the internal pressure of the gas supply pipe and the internal pressure of the first recovery pipe 360-1, and the differential pressure sensor 383-2 installed in the second recovery pipe 360-2 may measure a difference between the internal pressure of the gas supply pipe and the internal pressure of the second recovery pipe 360-2.

In the above-described exemplary embodiment of FIG. 9, the present invention has been described based on the case where the liquid supply pipe 230 is branched into the two liquid supply pipes 230-1 and 230-2 and the liquid remaining in the filters 293-1 and 293-2 installed in the pipes, respectively, is drained to the drain apparatus 2000 as an example. However, the present invention is not limited thereto, and the liquid supply pipe may be branched into three or more pipes, and the liquid remaining in the filter installed in each of the three or more pipes may be drained to the drain apparatus.

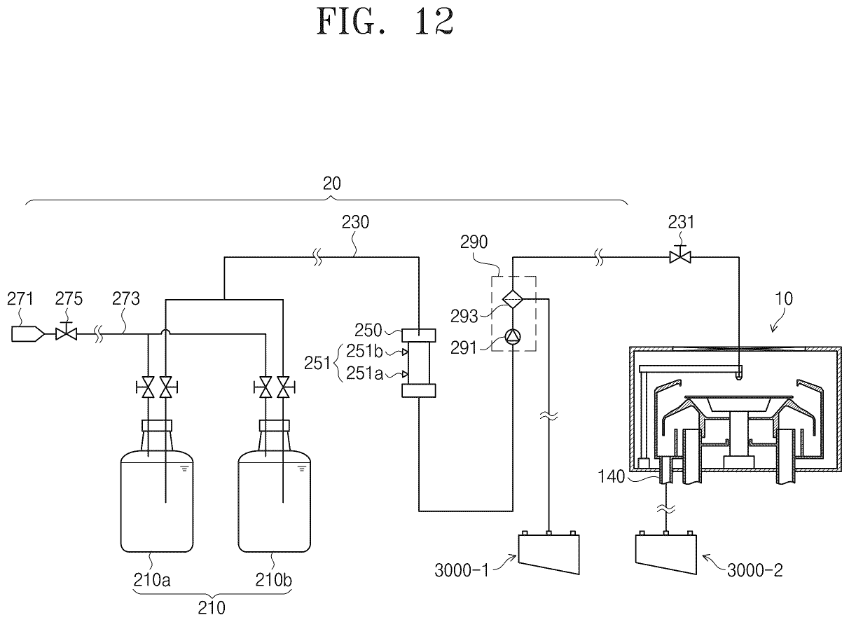

In the exemplary embodiment of FIG. 2 described above, the present invention has been described based on the case where the liquid remaining in the filter 293 installed in the liquid supply pipe 230 is drained to the drain apparatus 30 as an example. However, the present invention is not limited thereto, and as illustrated in FIG. 12, a second drain apparatus 3000-2 which drains a liquid discharged from the processing unit 10 through the discharge pipe 140 and discharges the liquid discharged to the outside may be provided separately from a first drain apparatus 3000-1 which drains and discharges a liquid remaining in the filter 293 to the outside. Also, unlike this, the first drain apparatus 3000-1 may not be provided, and only the second drain apparatus 3000-2 may be provided.

In the exemplary embodiment of FIG. 2 described above, the present invention has been described based on the case where the liquid remaining in the filter 293 inside the pump unit 290 is drained to the drain apparatus 30 as an example. However, unlike this, an external filter separate from the pump unit 290 may be installed in the liquid supply pipe 230, and a drain apparatus for discharging a liquid remaining in the external filter to the outside may be provided separately from the drain apparatus 30 for discharging a liquid remaining in the filter 293 in the pump unit 290 to the outside. However, unlike this, the external filter and the filter 293 in the pump unit 290 may drain the liquid remaining inside with one drain apparatus 30.

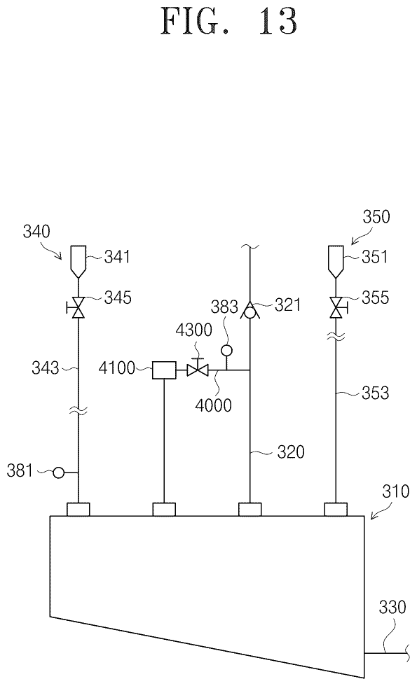

In the exemplary embodiments of FIGS. 4 to 5 described above, the present invention has been described based on the case where the recovery pipe 360 is connected to the suction port of the ejector 370 installed in the gas supply pipe 343 as an example. However, the present invention is not limited thereto, and as illustrated in FIG. 13, a recovery pipe 4000 may be branched from the inlet pipe 320 and may be directly connected to the drain box 310. The recovery pipe 4000 may be provided with a negative pressure forming unit 4100 for forming a negative pressure in the recovery pipe 4000. According to an example, the negative pressure forming unit 4100 may be an ejector. The liquid flowing back to the inlet pipe 320 flows to the recovery pipe 4000 by the negative pressure formed by the negative pressure forming unit 4100 and may be recovered to the drain box 310. The recovery pipe 4000 may be provided with an opening/closing valve 4300 for opening and closing the internal flow path thereof.

In the above-described exemplary embodiments of FIGS. 4 to 5, the present invention has been described based on the case where the bottom surface 312 of the drain box 310 is provided to be inclined downward from the first side surface 313 to the second side surface 314 as an example. However, unlike this, the bottom surface 312 may be provided flat.

In the exemplary embodiment of FIG. 5 described above, the present invention has been described based on the case where the differential pressure sensors 381 and 383 are installed in the gas supply pipe 343 and the recovery pipe 360 as an example. However, unlike this, the differential pressure sensor may be installed in the gas supply pipe and the drain box, or in the gas supply pipe and the inlet pipe.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a processing unit for processing a substrate;
a liquid supply unit for supplying a liquid to the substrate disposed in the processing unit; and
a drain apparatus for discharging a liquid drained from the processing unit or the liquid supply unit to the outside,
wherein the drain apparatus includes:
a drain box having an inner space;
an inlet pipe for flowing the liquid drained from the processing unit or liquid supply unit into the inner space;
a gas supply unit for supplying gas to the inner space through a gas supply pipe;
a discharge pipe for discharging the liquid in the inner space to the outside of the drain box; and
a recovery pipe that is branched from the inlet pipe and recovers a fluid flowing back to the inlet pipe from the inner space to the drain box.

2. The apparatus of claim 1, wherein a negative pressure forming unit is coupled to the recovery pipe.

3. The apparatus of claim 1, wherein the recovery pipe is connected to the gas supply pipe, and
an opening/closing valve is installed in the recovery pipe.

4. The apparatus of claim 1, wherein an ejector having an inlet, an outlet, and a suction port is installed in the gas supply pipe,
a pipe located on a gas supply source side in the gas supply pipe is connected to the inlet,
a pipe located on the drain box side in the gas supply pipe is connected to the outlet, and
the recovery pipe is connected to the suction port.

5. The apparatus of claim 4, wherein an opening/closing valve is installed in the recovery pipe, and
the drain apparatus further includes:
a differential pressure sensor for measuring a difference between a pressure of the gas supply pipe and a pressure of the recovery pipe; and
a controller for controlling the opening/closing valve installed in the recovery pipe based on a value measured by the differential pressure sensor.

6. The apparatus of claim 5, wherein the controller closes the opening/closing valve when a differential pressure measured by the differential pressure sensor exceeds a set value, and opens the opening/closing valve when the differential pressure measured by the differential pressure sensor is equal to or less than the set value.

7. The apparatus of claim 1, wherein a check valve for preventing backflow is installed in the inlet pipe upstream of a point where the recovery pipe is branched.

8. The apparatus of claim 1, wherein the drain apparatus further includes a dissolution liquid supply pipe for supplying a dissolution liquid for dissolving the liquid in the inner space to the inner space.

9. The apparatus of claim 1, wherein the liquid supply unit includes:
a bottle in which the liquid is stored;
a liquid supply pipe for supplying the liquid in the bottle to the processing unit; and
a filter installed in the liquid supply pipe, and
the filter has a drainage pipe coupled to the inlet pipe.

10. A drain apparatus for discharging a liquid, the drain apparatus comprising:
a drain box having an inner space;
an inlet pipe for flowing a liquid drained from an external configuration into the inner space;
a gas supply unit for supplying gas to the inner space through a gas supply pipe;
a dissolution liquid supply pipe for supplying a dissolution liquid into the inner space to dissolve the liquid in the inner space;
a discharge pipe for discharging the liquid in the inner space to the outside of the drain box; and
a recovery pipe that is branched from the inlet pipe and recovers a fluid flowing back to the inlet pipe from the inner space to the drain box.

11. The drain apparatus of claim 10, wherein the recovery pipe is connected to the gas supply pipe, and
an opening/closing valve is installed in the recovery pipe.

12. The drain apparatus of claim 10, wherein an ejector having an inlet, an outlet, and a suction port is installed in the gas supply pipe,
a pipe located on a gas supply source side in the gas supply pipe is connected to the inlet,
a pipe located on the drain box side in the gas supply pipe is connected to the outlet, and
the recovery pipe is connected to the suction port.

13. The drain apparatus of claim 12, wherein an opening/closing valve is installed in the recovery pipe, and
the drain apparatus further comprises:
a differential pressure sensor for measuring a difference between a pressure of the gas supply pipe and a pressure of the recovery pipe; and
a controller for controlling the opening/closing valve installed in the recovery pipe based on a value measured by the differential pressure sensor.

14. The drain apparatus of claim 13, wherein the controller closes the opening/closing valve when a differential pressure measured by the differential pressure sensor exceeds a set value, and opens the opening/closing valve when the differential pressure measured by the differential pressure sensor is equal to or less than the set value.

15. The drain apparatus of claim 10, wherein the inlet pipe includes:
a first inlet pipe for flowing a liquid drained from a first configuration into the inner space; and
a second inlet pipe for flowing a liquid drained from a second configuration into the inner space, and
the recovery pipe includes:
a first recovery pipe for recovering a fluid flowing back from the inner space to the first inlet pipe to the drain box; and
a second recovery pipe for recovering a fluid flowing back from the inner space to the second inlet pipe to the drain box.

16. The drain apparatus of claim 15, wherein the gas supply pipe is provided with a first ejector having a first inlet, a first outlet, and a first suction port, and a second ejector having a second inlet, a second outlet, and a second suction port,
a pipe located on a gas supply source side in the gas supply pipe is connected to the first inlet,
a pipe located on the drain box side in the gas supply pipe is connected to the first outlet,
the first recovery pipe is connected to the first suction port,
a pipe located on a gas supply source side in the gas supply pipe is connected to the second inlet,
a pipe located on the drain box side in the gas supply pipe is connected to the second outlet, and
the second recovery pipe is connected to the second suction port.

17. The drain apparatus of claim 16, further comprising:
a first differential pressure sensor for measuring a difference between a pressure of the gas supply pipe and a pressure of the first recovery pipe;
a second differential pressure sensor for measuring a difference between a pressure of the gas supply pipe and a pressure of the second recovery pipe;
a first opening/closing valve for opening/closing the first recovery pipe; and
a second opening/closing valve for opening/closing the second recovery pipe.

18. The drain apparatus of claim 17, further comprising:
a controller for controlling the first opening/closing valve and the second opening/closing valve,
the controller closes the first opening/closing valve when a differential pressure measured by the first differential pressure sensor exceeds a set value, and opens the first opening/closing valve when the differential pressure measured by the first differential pressure sensor is equal to or less than the set value, and closes the second opening/closing valve when a differential pressure measured by the second differential pressure sensor exceeds a set value, and opens the second opening/closing valve when the differential pressure measured by the second differential pressure sensor is equal to or less than the set value.

19. An apparatus for processing a substrate, the apparatus comprising:
a processing unit for processing a substrate;
a liquid supply unit for supplying a photoresist to the substrate disposed in the processing unit; and
a drain apparatus for discharging the photoresist drained from the liquid supply unit to the outside,
the drain apparatus includes:
a drain box having an inner space;
an inlet pipe for flowing the photoresist drained from the liquid supply unit into the inner space;
a gas supply unit for supplying gas to the inner space through a gas supply pipe;
a thinner supply pipe for supplying a thinner to dissolve the photoresist in the inner space;
a discharge pipe for discharging the liquid in the inner space to the outside of the drain box;
a recovery pipe that is branched from the inlet pipe and recovers a fluid flowing back to the inlet pipe from the inner space to the drain box;
an opening/closing valve for opening and closing the recovery pipe; and
an ejector installed in the gas supply pipe and having an inlet, an outlet, and a suction port, and
a pipe located on a gas supply source side of the gas supply pipe is connected to the inlet,
a pipe located on the drain box side in the gas supply pipe is connected to the outlet, and
the recovery pipe is connected to the suction port.

20. The apparatus of claim 19, further comprising:
a controller for controlling the drain apparatus,
wherein the drain apparatus further includes a differential pressure sensor that measures a difference between a pressure of the gas supply pipe and a pressure of the recovery pipe, and
the controller closes the opening/closing valve when a differential pressure measured by the differential pressure sensor exceeds a set value, and opens the opening/closing valve when the differential pressure measured by the differential pressure sensor is equal to or less than the set value.
